(19) United States
(12) Patent Application Publication
(10) Pub. No.: US 2022/0115460 A1
(43) Pub. Date: Apr. 14, 2022

(54) DISPLAY SUBSTRATE AND DISPLAY DEVICE

(71) Applicant: BOE TECHNOLOGY GROUP CO., LTD., Beijing (CN)

(72) Inventors: Haiyan SUN, Beijing (CN); Meishan XU, Beijing (CN); Xiaojin ZHANG, Beijing (CN); Changho LEE, Beijing (CN); Dan WANG, Beijing (CN)

(21) Appl. No.: 17/262,192

(22) PCT Filed: Apr. 9, 2020
(86) PCT No.: PCT/CN2020/084024

§ 371 Date: Jan. 21, 2021

(51) Int. Cl. H01L 27/32; H01L 51/50

(52) U.S. Cl. CPC H01L 27/3218; H01L 27/3246; H01L 51/5004; H01L 51/5072; H01L 51/5092; H01L 51/5056

(57) ABSTRACT

The present disclosure provides a display substrate and a display panel. The display substrate comprises: a base substrate, a first electrode layer, a first light-emitting layer, a first common connection layer, a second light-emitting layer, a third light-emitting layer, and a second electrode layer. The first electrode layer is provided on a side of the base substrate; the first light-emitting layer is provided on a side of the first electrode layer away from the base substrate; the first common connection layer is provided on a side of the first light-emitting layer away from the first electrode layer, and comprises a plurality of first sub-common connection layers; each second sub-light-emitting layer of the second light-emitting layer is provided on a side of each first sub-common connection layer away from the first light-emitting layer in one-to-one correspondence.

### CROSS-REFERENCE TO RELATED APPLICATION

This application is a 35 U.S.C. § 371 national phase application of International Application No. PCT/CN2020/084024 filed Apr. 9, 2020, the contents of which being incorporated by reference in their entirety herein.

### TECHNICAL FIELD

The present disclosure relates to the field of display technology, and in particular, to a display substrate and a display device.

### BACKGROUND

Comparing with traditional LCD (Liquid Crystal Display) display devices, OLED (Organic Light Emitting Diode) display devices require no backlight, and uses very thin organic material coatings and glass substrates. When current passes, these organic materials will glow. At the same time, the OLED display screen can be made lighter and thinner, with a larger viewing angle, and can significantly save power, so it has been widely used.

The existing OLED device structure generally includes a red, green, and blue sub-pixel solution and a white light OLED plus color film solution. Different from the white OLED device, the red, green, and blue sub-pixel solution involves separate preparations of RGB pixels, so fine masks (FMM) must be used in the thin film evaporation process.

However, the fine mask (FMM) used in OLED is currently monopolized by a few foreign manufacturers and the price is relatively high. In addition, in the process of fine mask, precise positioning of the mechanism is required, and the requirements for process equipment are relatively high, and various resulting defects are prone to occur, thereby increasing the manufacturing cost.

### SUMMARY

The purpose of the present disclosure is to provide a display substrate and a display device, which can reduce the number of fine masks in the preparation process of the display substrate and reduce the production cost.

According to an aspect of the present disclosure, there is provided a display substrate including:

a base substrate comprising a display area which comprises a plurality of pixel unit areas;

a first electrode layer provided on a side of the base substrate and comprising a plurality of sub-electrodes, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;

a first light-emitting layer provided on a side of the first electrode layer away from the base substrate, and an orthographic projection of the first light-emitting layer on the base substrate covering the display area;

a first common connection layer provided on a side of the first light-emitting layer away from the first electrode layer, used to transport holes, and comprising a plurality of first sub-common connection layers, wherein the first sub-common connection layers are provided in a one-to-one correspondence with the pixel unit areas, and an orthographic projection of each of the first sub-common connection layers on the base substrate is at least partially located on a corresponding pixel unit area and covers at least a part of orthographic projections of the first sub-electrode and the second sub-electrode on the base substrate;

a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate;

a third light-emitting layer provided on the side of the first common connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate;

a second electrode layer provided on a side of the first light-emitting layer, the second light-emitting layer and the third light-emitting layer away from the first electrode layer, and an orthographic projection of the second electrode layer on the base substrate covering orthographic projections of the first light-emitting layer, the second light-emitting layer, and the third light-emitting layer on the base substrate.

In an exemplary embodiment of the present disclosure, the orthographic projections of the second light-emitting layer and the third light-emitting layer on the base substrate do not overlap.

In an exemplary embodiment of the present disclosure, the display substrate further comprises:

a second common connection layer provided on a side of the first light-emitting layer away from the first electrode layer, used to transport the holes, and comprising a plurality of second sub-common connection layers; wherein the first common connection layer is located at a side of the second common connection layer away from the first light-emitting layer, and the first sub-common connection layers and the second sub-common connection layers are provided in one-to-one correspondence, and an orthographic projection of each of the second sub-common connection layers on the base substrate is at least partially located on a pixel unit area corresponding to it, and covers at least a part of the orthographic projections of the first sub-electrode and the second sub-electrode on the base substrate.

In an exemplary embodiment of the present disclosure, the display substrate further comprises:

a connection layer provided on the side of the first common connection layer away from the first light-emitting layer, used to transport the holes, and comprising a plurality of sub-connection layers; wherein the sub-connection layers and the pixel unit areas are provided in one-to-one correspondence, and an orthographic projection of each of the sub-connection layers on the base substrate is at least partially located within a range of the orthographic projection of the second sub-electrode on the base substrate; and the third light-emitting layer is provided on a side of the connection layer away from the first light-emitting layer, and the third sub-light-emitting layers and the sub-connection layers are provided in a one-to-one correspondence.

In an exemplary embodiment of the present disclosure, the display substrate further comprises:

a pixel defining layer provided on a side of the first electrode layer away from the base substrate, and a plurality of openings being formed on the pixel defining layer, wherein the openings are provided in one-to-one correspondence with the sub-electrodes, and the first light-emitting layer is provided on a side of the pixel defining layer away from the first electrode layer, and an orthographic projection of the first light-emitting layer on the base substrate covers an orthographic projection of each of the openings on the base substrate, and orthographic projections of the second sub-light-emitting layer and the third light-emitting layer on the base substrate are within orthographic projections of the openings on the base substrate.

In an exemplary embodiment of the present disclosure, the display substrate further comprises:

a hole injection layer provided on the side of the first electrode layer away from the base substrate;

a hole transport layer provided on a side of the hole injection layer away from the first electrode layer, wherein the first light-emitting layer is provided on a side of the hole transport layer away from the hole injection layer;

an electron transport layer provided on a side of the first light-emitting layer, the second light-emitting layer, and the third light-emitting layer away from the connecting layer;

an electron injection layer provided on a side of the electron transport layer away from the first light-emitting layer, and the second electrode layer being provided on a side of the electron injection layer away from the electron transport layer.

In an exemplary embodiment of the present disclosure, the display substrate further comprises:

an electron blocking layer provided on a side of the hole transport layer away from the hole injection layer, and the first light-emitting layer being provided on a side of the electron blocking layer away from the hole transport layer;

a hole blocking layer provided on a side of the first light-emitting layer, the second light-emitting layer, and the third light-emitting layer away from the electron blocking layer, and the electron transport layer being provided on a side of the hole blocking layer away from the third light-emitting layer.

In an exemplary embodiment of the present disclosure, a HOMO energy level difference between the first light-emitting layer and the electron blocking layer is 0˜0.3 eV.

In an exemplary embodiment of the present disclosure, a hole mobility of the first light-emitting layer is greater than or equal to 1×10⁻⁹ cm²/Vs.

In an exemplary embodiment of the present disclosure, a hole mobility of the first common connection layer is greater than or equal to 1×10⁻⁵ cm²/Vs.

In an exemplary embodiment of the present disclosure, the first electrode layer is an anode layer, and the second electrode layer is a common cathode layer.

In an exemplary embodiment of the present disclosure, the first light-emitting layer is a blue light-emitting layer, the second light-emitting layer is a green light-emitting layer, and the third light-emitting layer is a red light-emitting layer.

According to another aspect of the present disclosure, there is provided a display panel comprising the display substrate mentioned above.

In an exemplary embodiment of the present disclosure, the display substrate comprises:

a base substrate comprising a display area which comprises a plurality of pixel unit areas;

a first electrode layer provided on a side of the base substrate and comprising a plurality of sub-electrodes, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;

a hole injection layer provided on a side of the first electrode layer away from the base substrate;

a hole transport layer provided on a side of the hole injection layer away from the first electrode layer;

an electron blocking layer provided on a side of the hole transport layer away from the hole injection layer;

a first light-emitting layer provided on a side of the first electrode layer away from the base substrate, and an orthographic projection of the first light-emitting layer on the base substrate covering the display area;

a second common connection layer provided on a side of the first light-emitting layer away from the first electrode layer, used to transport the holes, and comprising a plurality of second sub-common connection layers; wherein an orthographic projection of each of the second sub-common connection layers on the base substrate is at least partially located on a pixel unit area corresponding to it, and covers at least a part of the orthographic projections of the first sub-electrode and the second sub-electrode on the base substrate;

a first common connection layer provided on a side of the second common connection layer away from the first light-emitting layer, used to transport holes, and comprising a plurality of first sub-common connection layers, wherein the first sub-common connection layers are provided in a one-to-one correspondence with the second sub-common connection layers, and an orthographic projection of each of the first sub-common connection layers on the base substrate is at least partially located on a corresponding pixel unit area and covers at least a part of orthographic projections of the first sub-electrode and the second sub-electrode on the base substrate;

a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate;

a connection layer provided on the side of the first common connection layer away from the first light-emitting layer, used to transport the holes, and comprising a plurality of sub-connection layers; wherein the sub-connection layers and the first sub-common connection layers are provided in one-to-one correspondence, and an orthographic projection of each of the sub-connection layers on the base substrate is at least partially located within a range of the orthographic projection of the second sub-electrode on the base substrate;

a third light-emitting layer provided on a side of the connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate;

a hole blocking layer provided on a side of the first light-emitting layer, the second light-emitting layer, and the third light-emitting layer away from the base substrate;

an electron transport layer provided on a side of the hole blocking layer away from the base substrate;

an electron injection layer provided on a side of the electron transport layer away from the hole blocking layer;

a second electrode layer provided on a side of the electron injection layer away from the first electrode layer, and an orthographic projection of the second electrode layer on the base substrate covering orthographic projections of the first light-emitting layer, the second light-emitting layer, and the third light-emitting layer on the base substrate.

In an exemplary embodiment of the present disclosure, the display substrate comprises:

a base substrate comprising a display area which comprises a plurality of pixel unit areas;

a first electrode layer provided on a side of the electron blocking layer away from the hole transport layer, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;

a pixel defining layer provided on a side of the first electrode layer away from the base substrate, and a plurality of openings being formed on the pixel defining layer, wherein the openings are provided in one-to-one correspondence with the sub-electrodes;

a hole injection layer provided on a side of the pixel defining layer away from the first electrode layer, and an orthographic projection of the hole injection layer on the base substrate at least covering orthographic projections of the sub-electrodes on the base substrate;

a hole transport layer provided on a side of the hole injection layer away from the first electrode layer;

an electron blocking layer provided on a side of the hole transport layer away from the hole injection layer;

a first light-emitting layer provided on a side of the electron blocking layer away from the base substrate, and an orthographic projection of the first light-emitting layer on the base substrate covering an orthographic projection of each of the openings on the base substrate;

a second common connection layer provided on a side of the first light-emitting layer away from the first electrode layer, used to transport the holes, and comprising a plurality of second sub-common connection layers; wherein the second sub-common connection layers are provided in one-to-one correspondence with the pixel unit areas, and an orthographic projection of each of the second sub-common connection layers on the base substrate is at least partially located on a pixel unit area corresponding to it, and covers at least a part of the orthographic projections of the first sub-electrode and the second sub-electrode on the base substrate;

a first common connection layer provided on a side of the second common connection layer away from the first light-emitting layer, used to transport holes, and comprising a plurality of first sub-common connection layers, wherein the first sub-common connection layers are provided in a one-to-one correspondence with the second sub-common connection layers, and an orthographic projection of each of the first sub-common connection layers on the base substrate is at least partially located on a corresponding pixel unit area and covers at least a part of orthographic projections of the first sub-electrode and the second sub-electrode on the base substrate;

a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate, and an orthographic projection of the second light-emitting layer on the base substrate is located in orthographic projections of the openings on the base substrate;

a connection layer provided on the side of the first common connection layer away from the first light-emitting layer, used to transport the holes, and comprising a plurality of sub-connection layers; wherein the sub-connection layers and the first sub-common connection layers are provided in one-to-one correspondence, and an orthographic projection of each of the sub-connection layers on the base substrate is at least partially located within a range of the orthographic projection of the second sub-electrode on the base substrate;

a third light-emitting layer provided on a side of the connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate, and an orthographic projection of the third light-emitting layer on the base substrate is located in orthographic projections of the openings on the base substrate;

a hole blocking layer provided on a side of the first light-emitting layer, the second light-emitting layer, and the third light-emitting layer away from the base substrate;

an electron transport layer provided on a side of the hole blocking layer away from the base substrate;

an electron injection layer provided on a side of the electron transport layer away from the hole blocking layer;

a second electrode layer provided on a side of the electron injection layer away from the first electrode layer, and an orthographic projection of the second electrode layer on the base substrate covering orthographic projections of the first light-emitting layer, the second light-emitting layer, and the third light-emitting layer on the base substrate.

In an exemplary embodiment of the present disclosure, the display panel further comprises:

a light extraction layer provided on a side of the second electrode layer away from the third light-emitting layer;

an encapsulation layer provided on a side of the light extraction layer away from the second electrode layer.

### BRIEF DESCRIPTION OF THE DRAWINGS

The accompanying drawings are used to provide a further understanding of the embodiments of the present disclosure, and constitute a part of the specification, and are used to explain the present disclosure together with the embodiments of the present disclosure, and do not constitute a limitation to the present disclosure. The above and other features and advantages will become more apparent to those skilled in the art by describing detailed exemplary embodiments with reference to the accompanying drawings. In the accompanying drawings:

FIG. 1 is a schematic structural diagram of a display substrate provided by an embodiment of the disclosure;

FIG. 2 is a schematic structural diagram of a display substrate provided by an embodiment of the disclosure;

FIG. 3 is a schematic structural diagram of a display substrate provided by an embodiment of the disclosure;

FIG. 4 is a schematic structural diagram of a display substrate provided by an embodiment of the disclosure;

FIG. 5 is a schematic structural diagram of a display substrate provided by an embodiment of the disclosure;

FIG. 6 is a schematic structural diagram of a display substrate provided by another embodiment of the disclosure;

FIG. 7 is a schematic structural diagram of a display substrate provided by another embodiment of the present disclosure;

FIG. 8 is a schematic diagram of a Real RGB pixel arrangement according to an embodiment of the disclosure;

FIG. 9 is a mask for a pixel arrangement shown in FIG. 8 provided by an embodiment of the disclosure;

FIG. 10 is a schematic diagram of a Real RGB pixel arrangement according to an embodiment of the disclosure;

FIG. 11 is a mask for the pixel arrangement shown in FIG. 10 provided by an embodiment of the disclosure;

FIG. 12 is a schematic diagram of a SPR pixel arrangement according to an embodiment of the disclosure;

FIG. 13 is a mask for the pixel arrangement shown in FIG. 12 provided by an embodiment of the disclosure.

### DESCRIPTION OF REFERENCE SIGNS

100: base substrate; 110: first electrode layer; 120: second electrode layer; 130: pixel defining layer; 140: opening;
210: hole injection layer; 220: hole transport layer: 230: electron blocking layer; 240: hole blocking layer; 250: electron transport layer; 260: electron injection layer;
310: first light-emitting layer; 320: second light-emitting layer; 330: third light-emitting layer;
410: first common connection layer; 420: second common connection layer; 430: connection layer;
500: light extraction layer;
600: encapsulation layer;
710: first sub-pixel; 720: second sub-pixel; 730: third sub-pixel;
810: first mask: 820: second mask; 830: third mask.

### DETAILED DESCRIPTION

Exemplary embodiments will now be described more fully with reference to the accompanying drawings. However, the exemplary embodiments can be implemented in various forms, and should not be construed as being limited to the embodiments set forth herein; on the contrary, these embodiments are provided so that the present invention will be comprehensive and complete, and fully convey the concept of the example embodiments to those skilled in the art. The same reference numerals in the figures represent the same or similar structures, and thus their detailed descriptions will be omitted.

Although relative terms such as “upper” and “lower” are used in this specification to describe the relative relationship between one component of an icon and another component, these terms are used in this specification only for convenience, for example, according to the direction of the example described in the drawings. It can be understood that if the device of the icon is turned over and turned upside down, the component described as “upper” will become the “lower” component. When a structure is “on” another structure, it may mean that a certain structure is integrally formed on another structure, or that a certain structure is “directly” provided on another structure, or that a certain structure is “indirectly” provided on another structure through another structure. On other structures.

The terms “a”, “an”, “the”, and “said” are used to indicate the presence of one or more elements/components/etc.; the terms “including” and “have” are used to indicate open-ended inclusion and means that there may be other elements/components/etc. besides the listed elements/components/etc.; the terms “first”, “second”, etc. are only used as marks, not the quantity of their objects limit.

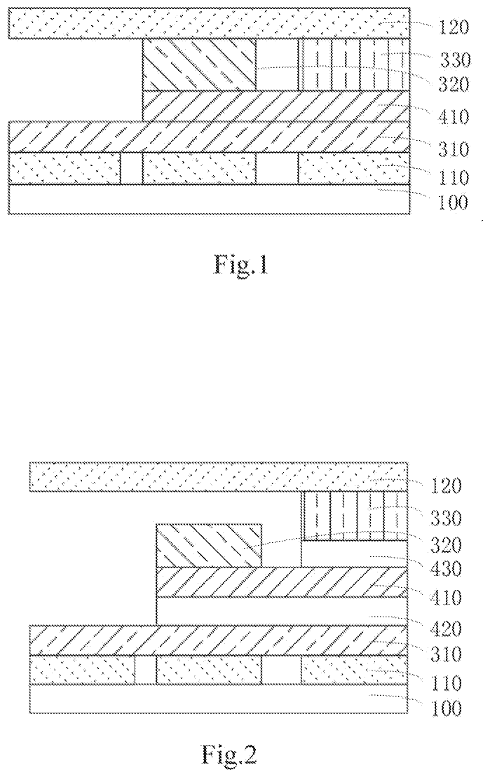

The embodiments of the present disclosure provide a display substrate. As shown in FIG. 1, the display substrate includes: a base substrate 100, a first electrode layer 110, a first light-emitting layer 310, a first common connection layer 410, and a second light-emitting layer 320, the third light-emitting layer 330 and the second electrode layer 120. The base substrate 100 includes a display area, and the display area includes a plurality of pixel unit areas. The first electrode layer 110 is provided on a side of the base substrate 100 and includes a plurality of sub-electrodes, and an orthographic projection of the first electrode layer 110 on the base substrate 100 is located in the display area, and each pixel unit area is provided with three sub-electrodes, and the three sub-electrodes include first sub-electrodes and second sub-electrodes adjacent to each other; the first light-emitting layer 310 is provided on a side of the first electrode layer 110 away from the base substrate 100, and an orthographic projection of the first light-emitting layer 310 on the base substrate 100 covers the display area. The first common connection layer 410 is provided on a side of the first light-emitting layer 310 away from the first electrode layer 110, is used to transport holes and block electrons, and includes a plurality of first sub-common connection layers. The first sub-common connection layers are provided in a one-to-one correspondence with the pixel unit areas. An orthographic projection of each of the first sub-common connection layers on the base substrate 100 is at least partially located on a corresponding pixel unit area, and covers at least part of the orthographic projections of the first sub-electrode and the second sub-electrode on the base substrate 100. The second light-emitting layer 320 is provided on a side of the first common connection layer 410 away from the first light-emitting layer 310, and includes a plurality of second sub-light-emitting layers, and the second sub-light-emitting layers are provided in one-to-one correspondence with the pixel unit areas, and an orthographic projection of each of the second sub-light-emitting layers on the base substrate 10 is at least partially located within a range of the orthographic projection of the first sub-electrode on the base substrate. The third light-emitting layer 330 is provided on the side of the first common connection layer 410 away from the first light-emitting layer 310, and includes a plurality of third sub-light-emitting layers, and the third sub-light-emitting layers are provided in a one-to-one correspondence with the pixel unit areas, an orthographic projection of each of the third sub-light-emitting layers on the base substrate 10 is at least partially located within a range of the orthographic projection of the second sub-electrode on the base substrate. The second electrode layer 120 is provided on a side of the first light-emitting layer 310, the second light-emitting layer 320, and the third light-emitting layer 330 away from the first electrode layer 110, and an orthographic projection of the second electrode layer 120 on the base substrate 100 covers orthographic projections of the first light-emitting layer 310, the second light-emitting layer 320 and the third light-emitting layer 330 on the base substrate 10.

Compared with the existing process, according to the display substrate provided by the present disclosure, by sharing the connection layer of the first light-emitting layer 310, the second light-emitting layer 320 and the third light-emitting layer 330, one evaporation chamber may be reduced (in the existing process, connection layers of the second light-emitting layer and the third light-emitting layer each needs to use a separate chamber), and two FMM processes may be reduced (in the existing process, the connection layers of the second light-emitting layer and the third light-emitting layer each requires a separate FMM process), thereby simplifying the process, saving equipment and material costs, and increasing unit productivity.

In addition, compared with the display substrate structure of the traditional RGB sub-pixels, in the display substrate provided by the present disclosure, each of the RGB devices has a life span that meets the current standard, and the voltage of the B device is reduced, and the efficiency is improved, which is better than that of the traditional process device; the voltages of the R and G devices are high, but the efficiency meets the current standard. As shown in Table 1, the devices can meet the application on vehicles, and the devices may also be replaced with better materials to further reduce the device voltage.

TABLE 1

| | | Current | | | |
|---|---|---|---|---|---|
| | | Density | Volt- | Effi- | Life |
| Display Substrate | | (mA/cm2) | age | ciency | Span |
| Blue | Display Substrate | 15 | 100% | 100% | 100% |
| Light | with the Traditional | | | | |
| | Process | | | | |
| | Display Substrate of | | 95.8% | 110% | 100% |
| | the disclosure | | | | |
| Green | Display Substrate | 15 | 100% | 100% | 100% |
| Light | with the Traditional | | | | |
| | Process | | | | |
| | Display Substrate | | 160% | 98% | 100% |
| | of the disclosure | | | | |
| Red | Display Substrate | 15 | 100% | 100% | 100% |
| Light | with the Traditional | | | | |
| | Process | | | | |
| | Display Substrate of | | 170% | 107% | 100% |
| | the disclosure | | | | |

For example, the orthographic projections of the second light-emitting layer 320 and the third light-emitting layer 330 on the base substrate 100 have no overlapping parts. By making the orthographic projections of the second light-emitting layer 320 and the third light-emitting layer 330 on the base substrate 100 have no overlapping portions, the crosstalk generated between the second light-emitting layer 320 and the third light-emitting layer 330 can be reduced, and display quality can be improved. Of course, the orthographic projections of the second light-emitting layer 320 and the third light-emitting layer 330 on the base substrate 100 may also have an overlapped portion, for example, the area of the overlapped portion is smaller than 10% of the orthographic projection area of the second light-emitting layer 320 on the base substrate 100, this is not limited by the disclosure.

For example, the first light-emitting layer 310 is formed by an open mask, the first light-emitting layer 310 is a blue light-emitting layer, and the host material in the blue light-emitting layer may be anthracene, fluorene, pyrene derivatives, and the guest material is a pyrene derivative, and the doping concentration is 0.5% to 5%, for example, 0.5%, 1%, 2%, 3%, 4%, 5%, etc., which are not listed here in this disclosure. The thickness of the blue light-emitting layer is 15 nm-25 nm, such as 15 nm, 17 nm, 20 nm, 23 nm, 25 nm, etc., which are not listed here in the present disclosure. Of course, the doping concentration may also be less than 0.5% or greater than 5%, and the thickness of the blue light-emitting layer may also be less than 15 nm or greater than 25 nm, which is not limited in the present disclosure.

In addition, considering the characteristics of red and green devices, the blue light-emitting layer is used as a common layer, and its host material needs to have a certain hole transport characteristic, and is tested by SCLC method (space charge limited current theory: when the space charge effect works, current passing through a space charge region is dominated by a drift current of carriers, and an electric field that determines this drift current is mainly generated by the carrier charges. Therefore, the carrier charges, the electric field and the current are mutually restricted at this time; that is, drift current of carriers passing through the space charge region must be limited by the corresponding space charge), and the hole mobility should not be lower than 1×10⁻⁹ cm²Ns, that is, the hole mobility of the first light-emitting layer 310 is greater than or equal to 1×10⁻⁹ cm²/Vs. As shown in Table 2, selecting materials with higher hole mobility can effectively reduce the device voltage and improve efficiency.

TABLE 2

| | | Electric | | | |
|---|---|---|---|---|---|
| Green Light | Hole | Current Density | | | Life |
| Unit | Mobility | (mA/cm²) | Voltage | Efficiency | Span |
| Device 1 | 100% | 15 | 100% | 100% | 100% |
| Device 2 | 400% | | 84% | 105% | 100% |

For example, the second light-emitting layer 320 is formed by FMM, and may be formed on a surface of the first common connection layer 410 away from the base substrate 100. The second light-emitting layer 320 is a green light-emitting layer, and the light-emitting host may be a bipolar single host, or a double host formed by a blend of a hole-type host and an electron-type host. The light-emitting guest can be various Ir, Pt-based metal complex green light materials, and the doping concentration is 5% to 15%, for example, 5%, 7%, 10%, 13%, 15%, etc. The present disclosure will not list one by one. The thickness of the green light-emitting layer is 25 nm-35 nm, such as 25 nm, 27 nm, 30 nm, 33 nm, 35 nm, etc., which are not listed here in the present disclosure. Of course, the doping concentration may also be less than 5% or greater than 15%, and the thickness of the blue light-emitting layer may also be less than 25 nm or greater than 35 nm, which is not limited in the present disclosure.

In addition, considering the life span of the green light device, the proportion of green light-emitting objects in the green light-emitting layer should not be less than 8%, and the optimization effect is shown in Table 3.

TABLE 3

| | Doping | Electric | | | |
|---|---|---|---|---|---|
| Green Light | Concen- | Current Density | | Effi- | Life |
| unit | tration | (mA/cm²) | Voltage | ciency | Span |
| Device 1 | 8% | 15 | 100% | 100% | 100% |
| Device 2 | 10% | | 99% | 98% | 195% |
| Device 3 | 12% | | 99% | 97% | 248% |

For example, the third light-emitting layer 330 is formed by FMM, and the third light-emitting layer 330 is a red light-emitting layer. The light-emitting host can be a bipolar single-host, or a double-host formed by a blend of a hole-type host and an electron-type host. The light-emitting guest can be a variety of Ir, Pt-based metal complex red light materials, and the doping concentration is adjusted in the range of 2% to 5%, for example, 2%, 3%, 4%, 5%, etc. The present disclosure will not list one by one. The thickness of the red light-emitting layer is 25 nm˜40 nm, such as 25 nm, 27 nm, 30 nm, 33 nm, 35 nm, etc., which are not listed here in the present disclosure. Of course, the doping concentration may also be less than 5% or greater than 15%, and the thickness of the blue light-emitting layer may also be less than 25 nm or greater than 35 nm, which is not limited in the present disclosure.

In addition, the first light-emitting layer 310, the second light-emitting layer 320, and the third light-emitting layer 330 may also be one color of R, B, and G, respectively, which is not limited in the present disclosure.

For example, the OLED structure on the display substrate of the present disclosure can be a top-emission type structure, and the first electrode layer 110 is a reflective anode, which can be prepared by a composite structure of a metal with high reflectivity and a transparent oxide layer with high work function, such as “Ag/ITO”, “Ag/IZO”, etc. The thickness of the metal layer is 80 nm to 100 nm, and the thickness of the metal oxide is 5 nm to 10 nm. The average reference value of the reflectivity of the visible light region of the anode is 85%˜95%; the second electrode layer 120 is a semi-reflective common cathode layer, which can be prepared by evaporation of Mg, Ag, Al films, or can be prepared by alloys such as Mg:Ag, and the thickness is 10 nm-20 nm. The mass ratio of Mg:Ag is adjusted between 3:7 to 1:9, and the reference range of the transmittance of the metal film layer at 530 nm is 50% to 60%. Of course, the OLED of the present disclosure may also be a bottom emission type.

For example, an orthographic projection of the first sub-common connection layer on the base substrate 100 is at least partially located on a corresponding pixel unit area, and covers at least a part of orthographic projections of the first and second sub-electrodes on the base substrate 100. An orthographic projection of the other of the three sub-electrodes in the pixel units except the first sub-electrode and the second sub-electrode on the base substrate 100 is not covered by an orthographic projection of the first sub-common connection layer on the base substrate 100. A notable function of the first common connection layer 410 is to reduce the injection barrier of holes from the first light-emitting layer 310 to the second light-emitting layer 320 and the third light-emitting layer 330. The material of the first common connection layer 410 needs to have a stable hole transport capability and can form a barrier to electron transport, which is equivalent to an electron blocking layer. When the second light-emitting layer 320 and the third light-emitting layer 330 emit light, the first common connection layer 410 can transport holes to the second light-emitting layer and the third light-emitting layer, and can has a certain blocking effect for transporting electrons from the second light-emitting layer and the third light-emitting layer to the first light-emitting layer, so as to prevent the part of the first light-emitting layer 310 under the first common connection layer 410 from emitting light, thereby improving the display performance.

Wherein, the host material of the first common connection layer 410 is a hole transport material, and materials such as HATCN, CuPc, etc. can be used to prepare a single layer film; the hole transport material may also be prepared by p-type doping, such as NPB: F4TCNQ, TAPC: MnO3, and the doping concentration can be 1%˜5%, for example, 1%, 2%, 3%, 4%, 5%, etc., which are not listed here in this disclosure. The thickness of the first common connection layer 410 is 10 nm to 30 nm, such as 10 nm, 15 nm, 20 nm, 25 nm, 30 nm, etc., which are not listed here in the present disclosure. Of course, the doping concentration may also be less than 1% or greater than 5%, and the thickness of the first common connection layer 410 may also be less than 10 nm or greater than 30 nm, which is not limited in the present disclosure.

In addition, considering the performance of the green light device, the first common connection layer 410 needs to have good hole transport characteristics, and the hole mobility should not be less than 1×10⁻⁵ cm²Ns when tested by the SCLC method, that is, the hole mobility of the first common connection layer 410 is greater than or equal to 1×10⁻⁵ cm²Ns. As shown in Table 4, materials with higher hole mobility are selected to effectively reduce the voltage of the device and increase the life span.

TABLE 4

| | | Electric | | | |
|---|---|---|---|---|---|
| Green Light | Hole | Current Density | | Effi- | Life |
| Unit | Mobility | (mA/cm²) | Voltage | ciency | Span |
| Device 1 | 100% | 15 | 100% | 100% | 100% |
| Device 2 | 130% | | 97% | 89% | 133% |

For example, as shown in FIG. 2, the display substrate further includes a connection layer 430. The connection layer 430 is disposed on a surface of the first common connection layer 410 away from the base substrate 100 and is disposed in the same layer as the second light-emitting layer 320, and the third light-emitting layer 330 is disposed on a surface of the connection layer 430 away from the first common connection layer 410. The connection layer 430 includes a plurality of sub-connection layers, and each third sub-light-emitting layer is provided on each sub-connection layer correspondingly. An orthographic projection of the sub-connection layer on the base substrate 100 is at least partially located on an orthographic projection of the second sub-electrode on the base substrate 100. Specifically, the connection layer 430 and the third light-emitting layer 330 can be formed by a same FMM. The notable function of the connection layer 430 is to further reduce the injection barrier of holes from the first common connection layer 410 to the third light-emitting layer 330, and has a certain blocking effect for transporting electrons at the same time, and carbazole materials can be used. Wherein, the thickness of the connection layer 430 is 5 nm-20 nm, for example, 5 nm, 8 nm, 10 nm, 15 nm, 20 nm, etc., which are not listed here in the present disclosure. Of course, the thickness of the connection layer 430 may also be less than 10 nm or greater than 30 nm, which is not limited in the present disclosure. Wherein, the energy level difference of the highest occupied orbit (HOMO) between the first common connection layer 410 and the connection layer 430 is less than 0.3 eV.

For example, as shown in FIG. 2, the display substrate further includes a second common connection layer 420. The second common connection layer 420 is disposed on a side of the first light-emitting layer 310 away from the first electrode layer 110, and includes a plurality of second sub-common connection layers, and each first sub-common connection layer is correspondingly disposed on a surface of the second sub-common connection layer away from the first light-emitting layer 310. The second common connection layer 420 and the first common connection layer 410 can be formed by using a same open mask; for example, the open mask shown in FIGS. 11 and 13, and orthographic projections of the first sub-common connection layer and the second sub-common connection layer on the base substrate 100 covers orthographic projections of the adjacent second and third sub-light-emitting layers on the base substrate 100; for example, the open mask shown in FIG. 9 and the orthographic projections of the first sub-common connection layer and the second sub-common connection layer on the base substrate 100 covers the orthographic projections of the second sub-light-emitting layer and the third sub-light-emitting layer located in the same column or the same row on the base substrate 100. In addition, the display substrate may also include more common connection layers to carry out hole transport and reduce the barrier of hole injection from the first light-emitting layer 310 to the second light-emitting layer 320 and the third light-emitting layer 330, which is not limited in the present disclosure.

Specifically, the second common connection layer 420 is generally used to improve the performance of the red and green devices, while taking into account the performance of the blue device. The host material of the second common connection layer 420 needs to have a stable hole transport capability and at the same time form a certain barrier to electron transport. For example, the host material can be a carbazole material with higher hole mobility, and the host material is prepared by P-type doping, with a doping concentration of 1%-5%, for example, 1%, 2%, 3%, 4%, 5%, etc., which are not listed here in this disclosure. The thickness of the second common connection layer 420 is 0˜10 nm, such as 1 nm, 3 nm, 5 nm, 8 nm, 10 nm, etc., which are not listed here in the present disclosure. Of course, the doping concentration may also be less than 1% or greater than 5%, and the thickness of the second common connection layer 420 may also be less than 10 nm or greater than 30 nm, which is not limited in the present disclosure. The first common connection layer 410 and the second common connection layer 420 may be the same material or the same type of material.

Wherein, the thickness of the second common connection layer 420 can be 0, that is, the second common connection layer 420 (i.e., a P-type doped layer) may be selectively provided between the first light-emitting layer 310 and the first common connection layer 410. Since the first light-emitting layer 310 and the first common connection layer 410 need good hole transport characteristics, the second common connection layer 420 may significantly affect the voltage and life span of the red and green devices, and the choice should be made according to actual conditions. The optimization effect is shown in Table 5.

TABLE 5

| | | Electric | | | |
|---|---|---|---|---|---|
| | | Current | | | |
| | | Density | Volt- | Effi- | Life |
| | Color | (mA/cm²) | age | ciency | Span |
| Device 1 (Without | Green | 15 | 100% | 100% | 100% |
| second common | Light Unit | | | | |
| connection layer) | Red Light | | 100% | 100% | 100% |
| | Unit | | | | |
| Device 2 (With | Green | | 96% | 96% | 110% |
| second common | Light Unit | | | | |
| connection layer) | Red Light | | 99% | 91% | 125% |
| | Unit | | | | |

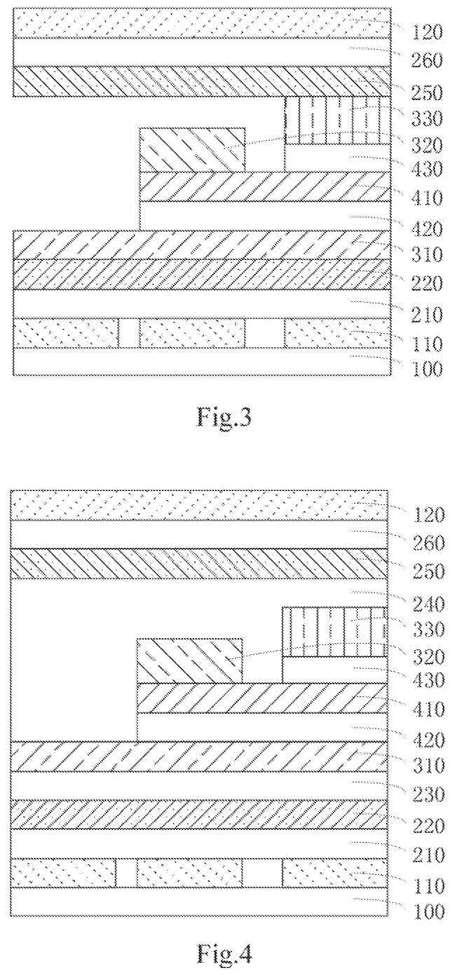

For example, as shown in FIG. 3, the display substrate further includes: a hole injection layer 210, a hole transport layer 220, an electron transport layer 250, and an electron injection layer 260. The hole injection layer 210 is provided on a side of the first electrode layer 110; the hole transport layer 220 is provided on a side of the hole injection layer 210 away from the first electrode layer 110, and the first light-emitting layer 310 is provided on a side of the hole transport layer 220 away from the hole injection layer 210; the electron transport layer 250 is provided on a side of the third light-emitting layer 330 away from the connection layer 430; the electron injection layer 260 is provided on a side of the electron transport layer 250 away from the third light-emitting layer 330, and the second electrode is provided on a side of the electron injection layer 260 away from the electron transport layer 250. Specifically, the hole injection layer 210 may be provided on a surface of the base substrate 100 and cover each of the sub-electrodes, and the orthographic projection on the base substrate 100 may cover the display area; the hole transport layer 220 may be provided on a surface of the hole injection layer 210 away from the first electrode layer 110, and the orthographic projection on the base substrate 100 covers the display area; the first light-emitting layer 310 may be provided on a surface of the hole transport layer 220 away from the hole injection layer 210; the electron transport layer 250 may be provided on a surface of the first light-emitting layer 310, the second light-emitting layer 320, and the third light-emitting layer 330 away from the connection layer 430, and the orthographic projection on the base substrate 100 covers the display area; the electron injection layer 260 may be provided on a surface of the electron transport layer 250 away from the first light-emitting layer 330 and the orthographic projection on the base substrate 100 covers the display area, and the second electrode may be provided on a surface of the electron injection layer 260 away from the electron transport layer 250.

Specifically, the notable function of the hole injection layer 210 is to reduce the hole injection barrier and improve the hole injection efficiency. For example, the hole injection layer 21 can be made of materials such as HATCN, CuPc, etc. to prepare a single layer film; it may also be prepared by p-type doping of hole transport materials, such as NPB: F4TCNQ, TAPC: MnO3, and so on. Wherein, the thickness of the hole injection layer 210 is 5 nm-20 nm, such as 5 nm, 8 nm, 10 nm, 15 nm, 20 nm, etc., which are not listed in this disclosure; the p-doping concentration is 0.5%˜10%, for example, 0.5%, 1%, 2%, 5%, 8%, 10%, etc., which are not listed here in this disclosure. Of course, the doping concentration may also be less than 0.5% or greater than 10%, and the thickness of the second common connection layer 420 may also be less than 5 nm or greater than 20 nm, which is not limited in the present disclosure.

For example, the hole transport layer 220 may be prepared by vapor deposition using a carbazole material with higher hole mobility. The highest occupied orbital (HOMO) energy level of the material of the hole transport layer 220 needs to be between −5.2 eV and 5.6 eV. The thickness of the hole transport layer 220 is 100 nm˜140 nm, such as 100 nm, 110 nm, 120 nm, 130 nm, 140 nm, etc., which are not listed here in the present disclosure. Of course, the thickness of the hole transport layer 220 may also be less than 100 nm or greater than 140 nm, which is not limited in the present disclosure.

For example, the electron transport layer 250 can be prepared by blending thiophenes, imidazoles, or azine derivatives with lithium quinolate, and the proportion of lithium quinolate can be adjusted within a range of 30%˜70%. The thickness of the structure 12 is adjusted between 20 nm and 40 nm.

For example, the electron injection layer 260 can be prepared by evaporation of materials such as LiF, LiQ, Yb, Ca, etc. The thickness of the electron injection layer 260 is 0.5 nm-2 nm, such as 0.5 nm, 0.4 nm, 1 nm, 1.5 nm, 2 nm, etc. The disclosure is not listed here. Of course, the thickness of the hole transport layer 220 may also be less than 0.5 nm or greater than 2 nm, which is not limited in the present disclosure.

For example, as shown in FIG. 4, the display substrate further includes: an electron blocking layer 230 and a hole blocking layer 240. The electron blocking layer 230 is provided on a side of the hole transport layer 220 away from the hole injection layer 210, and the first light-emitting layer 310 is provided on a side of the electron blocking layer 230 away from the hole transport layer 220; the electron blocking layer 230 may be provided on a surface of the hole transport layer 220 away from the hole injection layer 210, and the orthographic projection on the base substrate 100 covers the display area, and the first light-emitting layer 310 is provided on a surface of the electron blocking layer 230 away from the hole transport layer 220; the hole blocking layer 240 is provided on the side of the first light-emitting layer 310, the second light-emitting layer 320, and the third light-emitting layer 330 away from the electron blocking layer 230, and the electron transport layer 250 is provided on a side of the hole blocking layer 240 away from the third light-emitting layer 330; the hole blocking layer 240 may be provided on a surface of the first light-emitting layer 310, the second light-emitting layer 320, and the third light-emitting layer 330 away from the electron blocking layer 230, and an orthographic projection on the base substrate 100 covers the display area, and the electron transport layer 250 may be provided on a surface of the hole blocking layer 240 away from the third light-emitting layer 330. The electron blocking layer 230 is used for transferring holes and blocking electrons and the hole blocking layer 240 is used for transferring electrons and blocking holes.

For example, the thickness of the electron blocking layer 230 is 1 nm-10 nm, such as 1 nm, 2 nm, 5 nm, 8 nm, 10 nm, etc., which are not listed here one by one. Of course, the thickness of the hole transport layer 220 may also be less than 1 nm or greater than 10 nm, which is not limited in the present disclosure.

In addition, considering the characteristics of the OLED display device, the HOMO energy level difference between the materials of the electron blocking layer 230 and the hole transport layer 220 is 0˜0.3 eV, and the HOMO energy level difference between the materials of the electron blocking layer 230 and the first light-emitting layer 310 is 0˜0.3 eV, which is mainly used to increase the blue light life span and reduce the voltage of the green light device. The optimization effect is shown in Table 6.

TABLE 6

| | | HOMO Energy | | | | | |
|---|---|---|---|---|---|---|---|
| | | Level Difference | | Electric Current | | | |
| | | between Structure | | Density | | | |
| Color | Device | 4 and Structure 5 | | (mA/cm²) | Voltage | Efficiency | Life Span |
| Green | Device 1 | 0.3 | eV | 15 | 100% | 100% | 100% |
| Light | Device 2 | 0.2 | eV | | 98% | 102% | 125% |
| | Device 3 | 0.05 | eV | | 96% | 102% | 250% |
| Blue | Device 1 | 0.3 | eV | | 100% | 100% | 100% |
| Light | Device 2 | 0.2 | eV | | 99% | 94% | 85% |
| | Device 3 | 0.05 | eV | | 100% | 88% | 111% |

For example, the thickness of the hole blocking layer 240 is 2 nm-10 nm, such as 1 nm, 2 nm, 5 nm, 8 nm, 10 nm, etc., which are not listed here one by one. Of course, the thickness of the hole transport layer 220 may also be less than 1 nm or greater than 10 nm, which is not limited in the present disclosure.

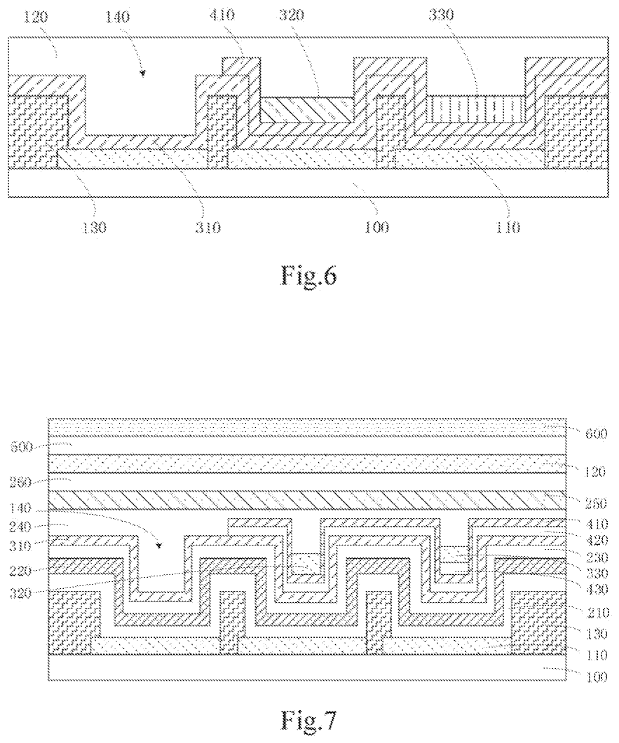

For example, as shown in FIGS. 6 and 7, the display substrate further includes a pixel defining layer (PDL) 130. The pixel defining layer 130 is disposed on the side of the first electrode layer 110 away from the base substrate 100, and includes a plurality of openings 140, and the openings 140 are provided in one-to-one correspondence with the sub-electrodes. The first light-emitting layer 310 is disposed on a side of the pixel defining layer 130 away from the first electrode layer 110, and an orthographic projection on the base substrate 100 covers an orthographic projection of each opening 140 on the base substrate 100, and orthographic projections of the second sub-light-emitting layer and the third light-emitting layer on the base substrate 100 are located in orthographic projections of the openings 140 on the base substrate 100. By providing the pixel defining layer 130, a barrier is formed between adjacent sub-electrodes, thereby avoiding leakage current between adjacent sub-sub-electrodes, thereby avoiding cross-color, thereby improving display quality.

Specifically, as shown in FIG. 7, the pixel defining layer 130 can be provided on the surface of the base substrate 100, the sub-electrodes in the first electrode layer 110 can be exposed from the openings 140, and the hole injection layer 210 can be provided on a surface of the pixel defining layer 130 away from the base substrate 100 and covers each sub-electrode in the openings 140.

In addition, in order to obtain a top-emitting device with high efficiency and high color purity, the structural characteristics of the optical micro-cavity should be considered when designing the above structure. For the total thickness of each layer of the red, green, and blue devices, the basic conditions of micro-cavity interference should be met:

$$2 {\sum }_{i = 1}^{k} {n}_{i} {r}_{i} + \frac{φ}{2 π} λ = k λ , K = 0 , 1 , 2 , 3 …$$

Here nᵢ is the refractive index corresponding to the organic layer i, rᵢ is the actual thickness corresponding to the organic layer i, and λ is the interference wavelength. The reference values of λ for the red, green, and blue pixels in this application are 620 nm, 530 nm, and 460 nm respectively. ψ represents the phase shift caused by the reflecting surface. k is a natural number, and the reference value of k in the present disclosure is 1, which is the first interference period. According to the display substrate proposed in the present disclosure, all the layers involved in the blue light unit are common layers. Therefore, it is necessary to comprehensively consider the overall thickness of the hole injection layer 210, the hole transport layer 220, the electron blocking layer 230, the blue light-emitting layer, the hole blocking layer 240, the hole transport layer 220, etc. to meet the blue micro-cavity conditions. The micro-cavity adjustment can be performed by changing the thickness of the hole transport layer 220 and the electron blocking layer 230 to obtain optimal optical and electrical properties. For the common connection layer of the red and green units, the length of the micro-cavity can be adjusted by the thickness of the non-common layer (such as the red light connection layer and the red light-emitting layer, the green light-emitting layer).

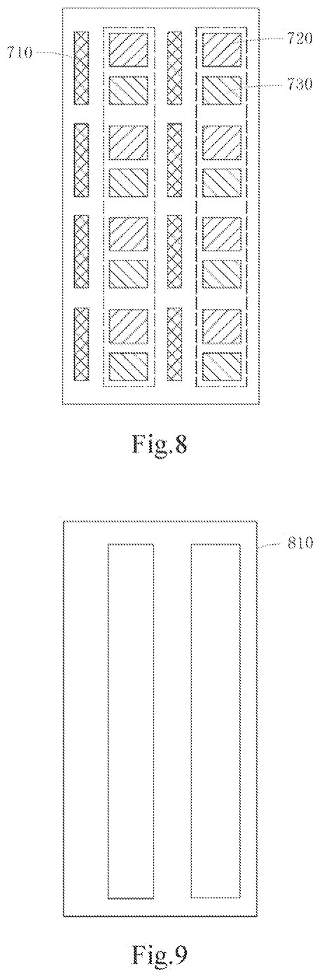

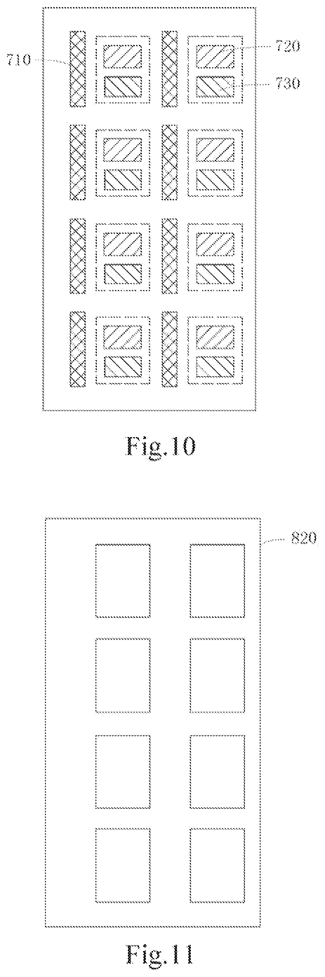

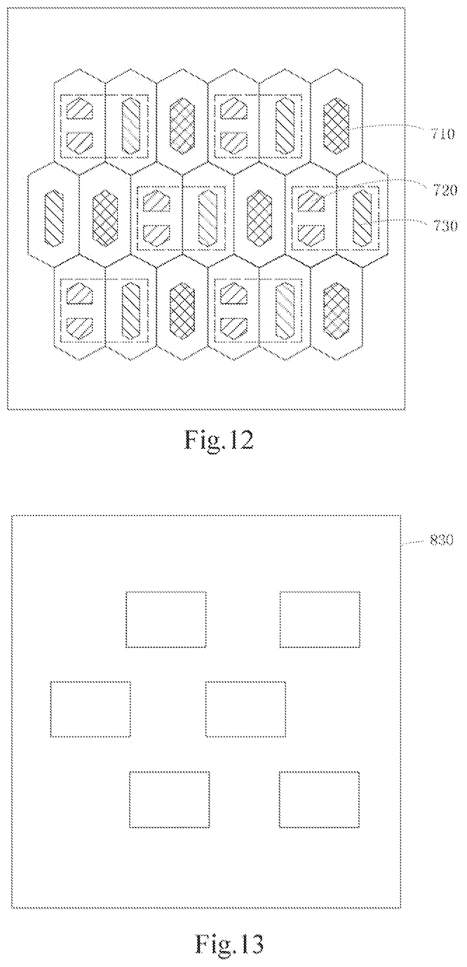

The first common connection layer 410 and the second common connection layer 420 of the present disclosure are the common connection layers of the second light-emitting layer 320 and the third light-emitting layer 330, which can be formed by using an open mask to save the use of FMM. For the Real RGB pixel arrangement shown in FIG. 8, the open mask can be designed as a first mask 810 shown in FIG. 9; for the Real RGB pixel arrangement shown in FIG. 10, the open mask can be designed as a second mask 820 shown in FIG. 11; for the SPR pixel arrangement shown in FIG. 12, the open mask can be designed as a third mask 830 shown in FIG. 13. Wherein, FIG. 8, FIG. 10 and FIG. 12 include blue light sub-pixel 710, green light sub-pixel 720 and red light sub-pixel 730.

The present disclosure also provides a display panel including the above-mentioned display substrate.

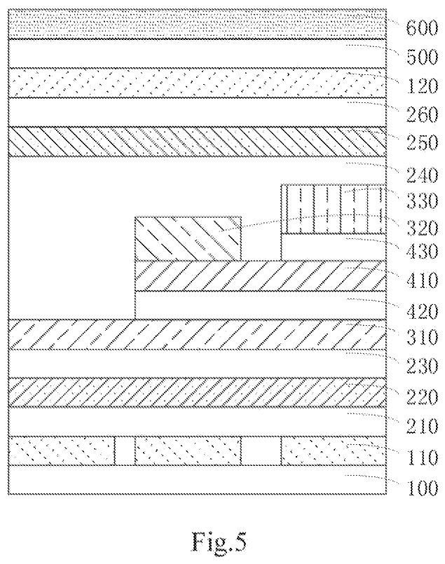

For example, as shown in FIG. 5, the display substrate may include: a base substrate 100, a first electrode layer 110, a hole injection layer 210, a hole transport layer 220, an electron blocking layer 230, a first light-emitting layer 310, a second common connection layer 420, a first common connection layer 410, second light-emitting layer 320, a connection layer 430, a third light-emitting layer 330, a hole blocking layer 240, an electron transport layer 250, an electron injection layer 260, and a second electrode layer 120.

Specifically, the base substrate 100 includes a display area, and the display area includes a plurality of pixel unit areas; the first electrode layer 110 is provided on a side of the base substrate 100 and includes a plurality of sub-electrodes, and an orthographic projection of the first electrode layer 110 is on the base substrate 100 is located in the display area. Each pixel unit area is provided with three sub-electrodes, and the three sub-electrodes include adjacent first and second sub-electrodes; the hole injection layer 210 is provided on a side of the first electrode layer 110 away from the base substrate 100; the hole transport layer 220 is provided on a side of the hole injection layer 210 away from the first electrode layer 110; the electron blocking layer 230 is provided on a side of the hole transport layer 220 away from the hole injection layer 210; the first light-emitting layer 310 is provided on a side of the electron blocking layer 230 away from the base substrate 100, and the orthographic projection of the first light-emitting layer 310 on the base substrate 100 covers the display area; the second common connection layer 420 is provided on a side of the first light-emitting layer 310 away from the first electrode layer 110 and is used to transport holes and block electrons, and includes a plurality of second sub-common connection layers, and an orthographic projection of the second sub-common connection layer on the base substrate 100 is at least partially located on a corresponding pixel unit area and covering at least part of orthographic projections of the first sub-electrode and the second sub-electrode on the base substrate 100; the first common connection layer 410 is disposed on a side of the second common connection layer 420 away from the first light-emitting layer 310, is used to transport holes and block electrons, and includes a plurality of first sub-common connection layers, the first sub-common connection layers and the second sub-common connection layers are provided in one-to-one correspondence, and orthographic projections of the first sub-common connection layers on the base substrate 100 is at least partially located on the corresponding pixel unit areas, and covers at least part of the orthographic projections of the first and second sub-electrodes on the base substrate 100; second light-emitting layer 320 is provided on a side of the first common connection layer 410 away from the first light-emitting layer 310, and includes a plurality of second sub-light-emitting layers, and the second sub-light-emitting layers are provided in one-to-one correspondence with the pixel unit areas. Orthographic projection of the second sub-light-emitting layers on the base substrate 100 is at least partially located within the range of the orthographic projection of the first sub-electrode on the base substrate; the connection layer 430 is provided on a side of the first common connection layer 410 away from the first light-emitting layer 310 and is used to transmit holes, block electrons and includes a plurality of sub-connection layers. The sub-connection layers are provided in one-to-one correspondence with the first sub-common connection layers. Orthographic projections of the sub-connection layers on the base substrate 100 are at least partially located on orthographic projections of the second sub-electrode on the base substrate 100. The third light-emitting layer 330 is provided on a side of the connecting layer 430 away from the first light-emitting layer 310, and includes a plurality of third sub-light-emitting layers, and the third sub-light-emitting layers are provided in one-to-one correspondence with the pixel unit areas. Orthographic projections of the third sub-light-emitting layers on the base substrate 100 are at least partially within the range of the orthographic projections of the second sub-electrodes on the base substrate 100; the hole blocking layer 240 is provided on a side of the first light-emitting layer 310, the second light-emitting layer 320, and the second light-emitting layer away from the base substrate 100; the electron transport layer 250 is provided on a side of the hole blocking layer 240 away from the base substrate 100; the electron injection layer 260 is provided on a side of the electron transport layer 250 away from the hole blocking layer 240; the second electrode layer 120 is provided on a side of the electron injection layer 260 away from the first electrode layer 110, and an orthographic projection of the second electrode layer 120 on the base substrate 100 covers orthographic projections of the first light-emitting layer 310, the second light-emitting layer 320, and the third light-emitting layer 330 on the base substrate 100.

For example, as shown in FIG. 7, the display substrate may include: a base substrate 100, a first electrode layer 110, a hole injection layer 210, a hole transport layer 220, an electron blocking layer 230, a first light-emitting layer 310, a second common connection layer 420, a first common connection layer 410, a second light-emitting layer 320, a connection layer 430, a third light-emitting layer 330, a hole blocking layer 240, an electron transport layer 250, an electron injection layer 260, a second electrode layer 120.

Specifically, the base substrate 100 includes a display area, and the display area includes a plurality of pixel unit areas; the first electrode layer 110 is provided on a side of the base substrate 100 and includes a plurality of sub-electrodes, and an orthographic projection of the first electrode layer 110 is on the base substrate 100 is located in the display area. Each pixel unit area is provided with three sub-electrodes, and the three sub-electrodes include adjacent first and second sub-electrodes; the pixel defining layer 130 is disposed on the side of the first electrode layer 110 away from the base substrate 100, and a plurality of openings 140 are formed, and the openings 140 are provided in one-to-one correspondence with the sub-electrodes; the hole injection layer 210 is disposed on a side of the pixel defining layer 130 away from the base substrate 100, and the orthographic projection on the base substrate 100 at least covers the orthographic projection of each sub-electrode on the base substrate 100; the hole transport layer 220 is provided on a side of the hole injection layer 210 away from the first electrode layer 110; the electron blocking layer 230 is provided on the side of the hole transport layer 220 away from the hole injection layer 210; the first light-emitting layer 310 is provided on the side of the electron blocking layer 230 away from the base substrate 100, and the orthographic projection of first light-emitting layer 310 on the base substrate 100 covers the display area; the second common connection layer 420 is provided on the side of the first light-emitting layer 310 away from the first electrode layer 110, and is used to transport holes and block electrons, and includes a plurality of second sub-common connection layers, the orthographic projections of the second sub-common connection layers on the base substrate 100 is at least partially located on corresponding pixel unit areas, and covers at least part of the orthographic projections of the first and second sub-electrodes on the base substrate 100; the first common connection layer 410 is provided on the side of the second common connection layer 420 away from the first light-emitting layer 310, is used to transport holes and block electrons, and includes a plurality of first sub-common connection layers. The first sub-common connection layers and the second sub-common connection layers are provided in a one-to-one correspondence, and the orthographic projections of the first sub-common connection layers on the base substrate 100 is at least partially located on the corresponding pixel unit areas, and covers at least part of the orthographic projections of the first and second sub-electrodes on the base substrate 100; the second light-emitting layer 320 is provided on the side of the first common connection layer 410 away from the first light-emitting layer 310, and includes a plurality of second sub-light-emitting layer. The second sub-light-emitting layers and the pixel unit areas are provided in one-to-one correspondence, the orthographic projection of the second sub-light-emitting layer on the base substrate 100 is at least partially located within a range of the orthographic projection of the first sub-electrode on the base substrate, and the orthographic projection of the second light-emitting layer 320 on the base substrate 100 is located in the orthographic projections of the openings 140 on the base substrate 100; the connection layer 430 is provided on the side of the first common connection layer 410 away from the first light-emitting layer 310 for transporting holes and blocking electrons, and includes a plurality of sub-connection layers. The sub-connection layers are provided in one-to-one correspondence with the first sub-common connection layers. The orthographic projections of the sub-connection layers on the base substrate 100 are at least partially located in the range of the orthographic projection of the second sub-electrode on the base substrate 100; the third light-emitting layer 330 is provided on the side of the connecting layer 430 away from the first light-emitting layer 310, and includes a plurality of third sub-light-emitting layers. The third sub-light-emitting layers are provided in one-to-one correspondence with the pixel unit areas. The orthographic projections of the third light-emitting layers on the base substrate 100 are at least partially located within the range of the orthographic projections of the second sub-electrodes on the base substrate 100, and the orthographic projection of the third light-emitting layer 330 on the base substrate 100 is located in the orthographic projections of the openings 140 on the base substrate 100; the hole blocking layer 240 is disposed on the side of the first light-emitting layer 310, the second light-emitting layer 320, and the third light-emitting layer 330 away from the base substrate 100; the electron transport layer 250 is provided on the side of the hole blocking layer 240 away from the base substrate 100; the electron injection layer 260 is provided on the side of the electron transport layer 250 away from the hole blocking layer 240; the second electrode layer 120 is provided on the side of the electron injection layer 260 away from the first electrode layer 110, and the orthographic projection of the second electrode layer 120 on the base substrate 100 covers the orthographic projections of the first light-emitting layer 310, the second light-emitting layer 320, and the third light-emitting layer 330 on the base substrate 100.

For example, as shown in FIGS. 5 and 7, the display panel further includes a light extraction layer 500 and an encapsulation layer 600. The light extraction layer 500 is provided on a side of the second electrode layer 120 away from the third light-emitting layer 330, and the encapsulation layer 600 is provided on a side of the light extraction layer 500 away from the second electrode layer 120.

For example, the light extraction layer (CPL) 500 may be formed by evaporation of 50 nm-80 nm organic small molecule materials. The material of the light extraction layer 500 should have a refractive index greater than 1.8 at 460 nm. The packaging layer 600 can be formed by using sealant packaging or film packaging; the packaging layer 600 can be a one-layer or multi-layer structure.

Specifically, the display panel can be used in mobile phones, tablet computers or other terminal devices, and its beneficial effects can refer to the beneficial effects of the above-mentioned display substrate, which will not be described in detail here.

Those skilled in the art will easily think of other embodiments of the present disclosure after considering the specification and practicing the content disclosed herein. This application is intended to cover any variations, uses, or adaptive changes of the present disclosure, which follow the general principles of the present disclosure and include common knowledge or conventional technical means in the technical field not disclosed in the present disclosure. The description and embodiments are only regarded as exemplary, and the true scope and spirit of the present disclosure are pointed out by the claims.

1. A display substrate, comprising:
a base substrate comprising a display area which comprises a plurality of pixel unit areas;
a first electrode layer provided on a side of the base substrate and comprising a plurality of sub-electrodes, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;
a first light-emitting layer provided on a side of the first electrode layer away from the base substrate, and an orthographic projection of the first light-emitting layer on the base substrate covering the display area;
a first common connection layer provided on a side of the first light-emitting layer away from the first electrode layer, used to transport holes, and comprising a plurality of first sub-common connection layers, wherein the first sub-common connection layers are provided in a one-to-one correspondence with the pixel unit areas, and an orthographic projection of each of the first sub-common connection layers on the base substrate is at least partially located on a corresponding pixel unit area and covers at least a part of orthographic projections of the first sub-electrode and the second sub-electrode on the base substrate;
a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate;
a third light-emitting layer provided on the side of the first common connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate;
a second electrode layer provided on a side of the first light-emitting layer, the second light-emitting layer and the third light-emitting layer away from the first electrode layer, and an orthographic projection of the second electrode layer on the base substrate covering orthographic projections of the first light-emitting layer, the second light-emitting layer, and the third light-emitting layer on the base substrate.

2. The display substrate according to claim 1, wherein the orthographic projections of the second light-emitting layer and the third light-emitting layer on the base substrate do not overlap.

3. The display substrate of claim 1, wherein the display substrate further comprises:
a second common connection layer provided on a side of the first light-emitting layer away from the first electrode layer, used to transport the holes, and comprising a plurality of second sub-common connection layers; wherein the first common connection layer is located at a side of the second common connection layer away from the first light-emitting layer, and the first sub-common connection layers and the second sub-common connection layers are provided in one-to-one correspondence, and an orthographic projection of each of the second sub-common connection layers on the base substrate is at least partially located on a pixel unit area corresponding to it, and covers at least a part of the orthographic projections of the first sub-electrode and the second sub-electrode on the base substrate.

4. The display substrate of claim 1, wherein the display substrate further comprises:
a connection layer provided on the side of the first common connection layer away from the first light-emitting layer, used to transport the holes, and comprising a plurality of sub-connection layers; wherein the sub-connection layers and the pixel unit areas are provided in one-to-one correspondence, and an orthographic projection of each of the sub-connection layers on the base substrate is at least partially located within a range of the orthographic projection of the second sub-electrode on the base substrate; and the third light-emitting layer is provided on a side of the connection layer away from the first light-emitting layer, and the third sub-light-emitting layers and the sub-connection layers are provided in a one-to-one correspondence.

5. The display substrate of claim 1, wherein the display substrate further comprises:
a pixel defining layer provided on a side of the first electrode layer away from the base substrate, and a plurality of openings being formed on the pixel defining layer, wherein the openings are provided in one-to-one correspondence with the sub-electrodes, and the first light-emitting layer is provided on a side of the pixel defining layer away from the first electrode layer, and an orthographic projection of the first light-emitting layer on the base substrate covers an orthographic projection of each of the openings on the base substrate, and orthographic projections of the second sub-light-emitting layer and the third light-emitting layer on the base substrate are within orthographic projections of the openings on the base substrate.

6. The display substrate of claim 1, wherein the display substrate further comprises:
a hole injection layer provided on the side of the first electrode layer away from the base substrate;
a hole transport layer provided on a side of the hole injection layer away from the first electrode layer, wherein the first light-emitting layer is provided on a side of the hole transport layer away from the hole injection layer;
an electron transport layer provided on a side of the first light-emitting layer, the second light-emitting layer, and the third light-emitting layer away from the connecting layer;
an electron injection layer provided on a side of the electron transport layer away from the first light-emitting layer, and the second electrode layer being provided on a side of the electron injection layer away from the electron transport layer.

7. The display substrate of claim 6, wherein the display substrate further comprises:
an electron blocking layer provided on a side of the hole transport layer away from the hole injection layer, and the first light-emitting layer being provided on a side of the electron blocking layer away from the hole transport layer;
a hole blocking layer provided on a side of the first light-emitting layer, the second light-emitting layer, and the third light-emitting layer away from the electron blocking layer, and the electron transport layer being provided on a side of the hole blocking layer away from the third light-emitting layer.

8. The display substrate of claim 7, wherein a HOMO energy level difference between the first light-emitting layer and the electron blocking layer is 0˜0.3 eV.

9. The display substrate of claim 1, wherein a hole mobility of the first light-emitting layer is greater than or equal to 1×10⁻⁹ cm²/Vs.

10. The display substrate of claim 1, wherein a hole mobility of the first common connection layer is greater than or equal to 1×10⁻⁵ cm²/Vs.

11. The display substrate of claim 1, wherein the first light-emitting layer is a blue light-emitting layer, the second light-emitting layer is a green light-emitting layer, and the third light-emitting layer is a red light-emitting layer.

12. A display panel comprising the display substrate according to claim 1.

13. The display panel of claim 12, wherein the display substrate comprises:
a base substrate comprising a display area which comprises a plurality of pixel unit areas;
a first electrode layer provided on a side of the base substrate and comprising a plurality of sub-electrodes, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;
a hole injection layer provided on a side of the first electrode layer away from the base substrate;
a hole transport layer provided on a side of the hole injection layer away from the first electrode layer;
an electron blocking layer provided on a side of the hole transport layer away from the hole injection layer;
a first light-emitting layer provided on a side of the first electrode layer away from the base substrate, and an orthographic projection of the first light-emitting layer on the base substrate covering the display area;
a second common connection layer provided on a side of the first light-emitting layer away from the first electrode layer, used to transport the holes, and comprising a plurality of second sub-common connection layers; wherein an orthographic projection of each of the second sub-common connection layers on the base substrate is at least partially located on a pixel unit area corresponding to it, and covers at least a part of the orthographic projections of the first sub-electrode and the second sub-electrode on the base substrate;
a first common connection layer provided on a side of the second common connection layer away from the first light-emitting layer, used to transport holes, and comprising a plurality of first sub-common connection layers, wherein the first sub-common connection layers are provided in a one-to-one correspondence with the second sub-common connection layers, and an orthographic projection of each of the first sub-common connection layers on the base substrate is at least partially located on a corresponding pixel unit area and covers at least a part of orthographic projections of the first sub-electrode and the second sub-electrode on the base substrate;
a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate;
a connection layer provided on the side of the first common connection layer away from the first light-emitting layer, used to transport the holes, and comprising a plurality of sub-connection layers; wherein the sub-connection layers and the first sub-common connection layers are provided in one-to-one correspondence, and an orthographic projection of each of the sub-connection layers on the base substrate is at least partially located within a range of the orthographic projection of the second sub-electrode on the base substrate;
a third light-emitting layer provided on a side of the connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate;
a hole blocking layer provided on a side of the first light-emitting layer, the second light-emitting layer, and the third light-emitting layer away from the base substrate;
an electron transport layer provided on a side of the hole blocking layer away from the base substrate;
an electron injection layer provided on a side of the electron transport layer away from the hole blocking layer;
a second electrode layer provided on a side of the electron injection layer away from the first electrode layer, and an orthographic projection of the second electrode layer on the base substrate covering orthographic projections of the first light-emitting layer, the second light-emitting layer, and the third light-emitting layer on the base substrate.

14. The display panel of claim 12, wherein the display substrate comprises:
a base substrate comprising a display area which comprises a plurality of pixel unit areas;
a first electrode layer provided on a side of the electron blocking layer away from the hole transport layer, wherein an orthographic projection of the first electrode layer on the base substrate is located in the display area, and three sub-electrodes are provided in each of the pixel unit areas, and the three sub-electrodes comprise a first sub-electrode and a second sub-electrode adjacent to each other;
a pixel defining layer provided on a side of the first electrode layer away from the base substrate, and a plurality of openings being formed on the pixel defining layer, wherein the openings are provided in one-to-one correspondence with the sub-electrodes;
a hole injection layer provided on a side of the pixel defining layer away from the first electrode layer, and an orthographic projection of the hole injection layer on the base substrate at least covering orthographic projections of the sub-electrodes on the base substrate;
a hole transport layer provided on a side of the hole injection layer away from the first electrode layer;
an electron blocking layer provided on a side of the hole transport layer away from the hole injection layer;
a first light-emitting layer provided on a side of the electron blocking layer away from the base substrate, and an orthographic projection of the first light-emitting layer on the base substrate covering an orthographic projection of each of the openings on the base substrate;
a second common connection layer provided on a side of the first light-emitting layer away from the first electrode layer, used to transport the holes, and comprising a plurality of second sub-common connection layers; wherein the second sub-common connection layers are provided in one-to-one correspondence with the pixel unit areas, and an orthographic projection of each of the second sub-common connection layers on the base substrate is at least partially located on a pixel unit area corresponding to it, and covers at least a part of the orthographic projections of the first sub-electrode and the second sub-electrode on the base substrate;
a first common connection layer provided on a side of the second common connection layer away from the first light-emitting layer, used to transport holes, and comprising a plurality of first sub-common connection layers, wherein the first sub-common connection layers are provided in a one-to-one correspondence with the second sub-common connection layers, and an orthographic projection of each of the first sub-common connection layers on the base substrate is at least partially located on a corresponding pixel unit area and covers at least a part of orthographic projections of the first sub-electrode and the second sub-electrode on the base substrate;
a second light-emitting layer provided on a side of the first common connection layer away from the first light-emitting layer, and comprising a plurality of second sub-light-emitting layers, wherein the second sub-light-emitting layers are provided in a one-to-one correspondence with the pixel unit areas, and an orthographic projection of each of the second sub-light-emitting layers on the base substrate is at least partially located within a range of the orthographic projection of the first sub-electrode on the base substrate, and an orthographic projection of the second light-emitting layer on the base substrate is located in orthographic projections of the openings on the base substrate;
a connection layer provided on the side of the first common connection layer away from the first light-emitting layer, used to transport the holes, and comprising a plurality of sub-connection layers; wherein the sub-connection layers and the first sub-common connection layers are provided in one-to-one correspondence, and an orthographic projection of each of the sub-connection layers on the base substrate is at least partially located within a range of the orthographic projection of the second sub-electrode on the base substrate;
a third light-emitting layer provided on a side of the connection layer away from the first light-emitting layer, and comprising a plurality of third sub-light-emitting layers, wherein the third sub-light-emitting layers are provided in a one-to-one correspondence with the pixel unit areas, and an orthographic projection of each of the third sub-light-emitting layers on the base substrate is at least partially located within a range of the orthographic projection of the second sub-electrode on the base substrate, and an orthographic projection of the third light-emitting layer on the base substrate is located in orthographic projections of the openings on the base substrate;
a hole blocking layer provided on a side of the first light-emitting layer, the second light-emitting layer, and the third light-emitting layer away from the base substrate;
an electron transport layer provided on a side of the hole blocking layer away from the base substrate;
an electron injection layer provided on a side of the electron transport layer away from the hole blocking layer;
a second electrode layer provided on a side of the electron injection layer away from the first electrode layer, and an orthographic projection of the second electrode layer on the base substrate covering orthographic projections of the first light-emitting layer, the second light-emitting layer, and the third light-emitting layer on the base substrate.

15. The display panel according to claim 12, wherein the display panel further comprises:
a light extraction layer provided on a side of the second electrode layer away from the third light-emitting layer; and
an encapsulation layer provided on a side of the light extraction layer away from the second electrode layer.

16. A display panel comprising the display substrate according to claim 2.

17. A display panel comprising the display substrate according to claim 3.

18. A display panel comprising the display substrate according to claim 4.

19. A display panel comprising the display substrate according to claim 5.

20. A display panel comprising the display substrate according to claim 6.
